(19) United States
(12) Patent Application Publication
(10) Pub. No.: US 2025/0175305 A1
(43) Pub. Date: May 29, 2025

(54) METHOD AND COMMUNICATION APPARATUS FOR GENERATING AND SENDING ACKNOWLEDGMENT FRAME IN IEEE 802.15.4 NETWORK

(71) Applicant: ESPRESSIF SYSTEMS (SHANGHAI) CO., LTD., Shanghai (CN)

(72) Inventors: Shu CHEN, Shanghai (CN); Qin ZHANG, Shanghai (CN); Wenxu ZHANG, Shanghai (CN)

(21) Appl. No.: 18/725,101

(22) PCT Filed: Aug. 11, 2022
(86) PCT No.: PCT/CN2022/111802

§ 371 Date: Jun. 27, 2024

(30) Foreign Application Priority Data
Dec. 31, 2021 (CN) 202111662317.8

(51) Int. Cl. H04L 5/00; H03M 13/09; H04W 84/12

(52) U.S. Cl. CPC H04L 5/0053; H03M 13/09; H04W 84/12

(57) ABSTRACT

A method and a communication apparatus for generating and sending an acknowledgment frame in an IEEE 802.15.4 network, the method includes: receiving a message frame from an IEEE 802.15.4 network; parsing the message frame to determine whether the message frame needs to be continuously processed; determining whether the message frame needs to be replied with an acknowledgment frame; determining a frame version number of the message frame; if the frame version number is 0b00 or 0b01, obtaining a sequence code in a frame header of the message frame, and generating the acknowledgment frame in the form of an immediate acknowledgment frame; if the frame version number is 0b10, obtaining the sequence code in the frame header of the message frame, then triggering an interrupt service routine in a memory, and executing the interrupt service routine to generate the acknowledgment frame in the form of an enhanced acknowledgment frame.

### TECHNICAL FIELD

The present application relates to an IEEE 802.15.4 network, and more particularly, to a method for generating and sending an acknowledgment frame in an IEEE 802.15.4 network, and a communication apparatus for generating and sending an acknowledgment frame in an IEEE 802.15.4 network.

### BACKGROUND

IEEE 802.15.4 is a technical standard that defines the protocol for Low Rate Wireless Personal Area Networks (LR-WPANs). In this standard, a total of four MAC frame structures are defined, namely a beacon frame, a data frame, a MAC command frame and an acknowledgment frame. Wherein, the acknowledgment frame configured to confirm successful receipt of a frame. In the communication process, in order to ensure the reliability of communication between devices, the sending device usually requires the receiving device to return an acknowledgment frame after receiving the correct frame information, indicating to the sending device that the corresponding information has been correctly received. Specifically, in the IEEE 802.15.4 protocol, it is stipulated that a device sends an acknowledgment frame after a specified time period after receiving the last symbol of a data frame or a MAC command frame.

The first version of the IEEE 802.15.4 standard was IEEE 802.15.4-2003, released in 2003, followed by several revised versions, including four revisions in 2006, 2011, 2015 and 2004, which revised, supplemented, and expanded the corresponding functions, technologies, or applications.

In these revised versions of the IEEE 802.15.4 standard, certain modifications have been made to the provisions related to acknowledgment frames. In IEEE 802.15.4-2011 and earlier versions, only one type of acknowledgment frame needs to be supported, namely the Immediate Acknowledgment Frame (abbreviated to Imm-Ack).

Since 2015, in IEEE 802.15.4-2015 and subsequent versions thereof, the frame format of the MAC layer has been expanded to include requirements for acknowledgment frames. In particular, a new type of acknowledgment frame, Enhanced Acknowledgment (abbreviated to Enh-Ack), is introduced in IEEE 802.15.4-2015. The frame format of the enhanced acknowledgment frame is similar to that of a normal data frame. The frame format of the enhanced acknowledgment frame consists of a frame header (MHR), a frame trailer (MFR), and a MAC payload unit. The enhanced acknowledgment frame can carry more data information by the MAC payload unit than the original immediate acknowledgment frame.

For the existing wireless communication chips supporting 802.15.4 on the current market, with respect to the processing of acknowledgment frames, some of which do not support IEEE 802.15.4-2015 and subsequent versions, especially cannot send enhanced acknowledgment frames, such as TI's chip CC2538; some of which use software to generate immediate acknowledgment frames or enhanced acknowledgment frames for IEEE 802.15.4-2015 and subsequent versions, and then send the generated immediate acknowledgment frames or enhanced acknowledgment frames by hardware, and chips using such solution are, for example, Silicon Lab's chip EFR32; and some of which only generate immediate acknowledgment frames or enhanced acknowledgment frames by software for all versions of IEEE 802.15.4. Chips using such solution are, for example, Nordic Semiconductor's chip NRF52840. This method of parsing received message frame and generating acknowledgment frames by software will result in an increase in CPU time occupied by the interrupt service routine, which not only increases the system response delay, but also increase the power consumption of the device.

In summary, the current solutions that can support different versions of the IEEE 802.15.4 standard need to generate acknowledgment frames in different formats by the interrupt service routine in the software, which not only consumes high power, but also causes longer system response delay due to over-occupation of CPU time, which is not conducive to practical applications.

### SUMMARY

In response to the above problems of the existing IEEE 802.15.4 based wireless communication chips, the object of the present application is to provide a solution for generating and sending an acknowledgment frame in an IEEE 802.15.4 network.

In one aspect of the present application, a method for generating and sending an acknowledgment frame in an IEEE 802.15.4 network is provided. The method is performed by a communication apparatus, the communication apparatus includes a processor, a memory, and a communication module. The method includes: step 1: receiving, by the communication module of the communication apparatus, a message frame from the IEEE 802.15.4 network; step 2: parsing, by the communication module, the message frame to determine whether the message frame needs to be continuously processed; if yes, executing step 3; if no, discarding the message frame and not executing other steps; step 3: determining, by the communication module, whether the message frame needs to be replied with an acknowledgment frame; if yes, proceeding to step 4; if no, discarding the message frame and not executing other steps; step 4: determining, by the communication module, a frame version number of the message frame; if the frame version number of the message frame is 0b00 or 0b01, executing step 5a; if the frame version number of the message frame is 0b10, executing step 5b; step 5a: obtaining, by the communication module, a sequence code in a frame header of the message frame, and generating the acknowledgment frame in a form of an immediate acknowledgment frame, wherein the sequence code in the frame header of the message frame is used as a sequence code in a frame header of the immediate acknowledgment frame; and step 5b: obtaining, by the communication module, the sequence code in the frame header of the message frame, then triggering, by the communication module, an interrupt service routine in the memory, and executing, by a processor, the interrupt service routine to generate the acknowledgment frame in a form of an enhanced acknowledgment frame, wherein the sequence code in the frame header of the message frame is used as a sequence code in a frame header of the enhanced acknowledgment frame; wherein the immediate acknowledgment frame includes a frame header and a frame trailer, and the enhanced acknowledgment frame includes a frame header, a MAC payload and a frame trailer.

Preferably, after step 5a or step 5b, proceeding to step 6: sending, by the communication module, after waiting for an AIFS delay, the generated enhanced acknowledgment frame or the generated immediate acknowledgment frame.

Further preferably, a duration of the AIFS delay is 192 μs.

Preferably, in step 2, determining, based on a destination address or a CRC check code in the message frame, whether the message frame needs to be continuously processed; if the destination address in the message frame does not contain the address of the communication apparatus, or if the CRC check code is incorrect, then discarding the message frame and not executing other steps; otherwise, proceeding to step 3.

Preferably, in step 3, determining, based on a value of an acknowledgment request field in the message frame, whether it is needed to reply with the acknowledgment frame; if the value of the acknowledgment request field is 1, the acknowledgment frame is needed; if the value of the reply request field is 0, the acknowledgment frame is not needed.

Preferably, step 5a further includes: executing, by the processor, the interrupt service routine to set a subsequent frame pending bit in the frame header of the immediate acknowledgment frame, and if the communication apparatus has a subsequent data frame to be sent, setting a value of 1 for the subsequent frame pending bit, otherwise, setting a value of 0 for the subsequent frame pending bit.

Preferably, step 5b further includes: executing, by the processor, the interrupt service routine to set a subsequent frame pending bit in the frame header of the enhanced acknowledgment frame, and if the communication apparatus has a subsequent data frame to be sent, setting a value of 1 for the subsequent frame pending bit, otherwise, setting a value of 0 for the subsequent frame pending bit.

In another aspect of the present application, a communication apparatus for generating and sending an acknowledgment frame in an IEEE 802.15.4 network is provided. The communication apparatus includes a processor, a memory and a communication module, wherein the communication module of the communication apparatus is configured to receive a message frame from the IEEE 802.15.4 network and send the acknowledgment frame; the memory is configured to store an interrupt service routine; the communication module is also configured to: parse the message frame to determine whether the message frame needs to be continuously processed; determine whether the message frame needs to be replied with the acknowledgment frame; determine a frame version number of the message frame; wherein, the processor is configured to discard the message frame in response to determining that the message frame does not need to be replied with the acknowledgment frame; the communication module is configured to obtain a sequence code in a frame header of the message frame and generate the acknowledgment frame in a form of an immediate acknowledgment frame, in response to the frame version number of the message frame being 0b00 or 0b01; wherein the sequence code in the frame header of the message frame is used as a sequence code in a frame header of the immediate acknowledgment frame; the communication module is configured to obtain a sequence code in the frame header of the message frame and trigger the interrupt service routine in the memory, and the processor is configured to execute the interrupt service routine to generate the acknowledgment frame in a form of an enhanced acknowledgment frame, in response to the frame version number of the message frame being 0b10; wherein the sequence code in the frame header of the message frame is used as a sequence code in a frame header of the enhanced acknowledgment frame; wherein the immediate acknowledgment frame includes a frame header and a frame trailer, and the enhanced acknowledgment frame includes a frame header, a MAC payload and a frame trailer.

Preferably, in response to the generated enhanced acknowledgment frame or the generated immediate acknowledgment frame, the communication module is configured to, after waiting for an AIFS delay, send the generated enhanced acknowledgment frame or the immediate acknowledgment frame.

Further preferably, a duration of the AIFS delay is 192 μs.

Preferably, the communication module is configured to determine, based on a destination address or a CRC check code in the message frame, whether the message frame needs to be continuously processed; if the destination address in the message frame does not contain the address of the communication apparatus, or if the CRC check code is incorrect, then the communication module is configured to discard the message frame and not execute other steps; otherwise, proceed to process the message frame.

Preferably, the communication module is configured to determine, based on a value of an acknowledge request field in the message frame, whether it is needed to reply with the acknowledgment frame; if the value of the acknowledgment request field is 1, the acknowledgment frame is needed; if the value of the reply request field is 0, the acknowledgment frame is not needed.

Preferably, in response to the frame version number of the message frame being 0b00 or 0b01, the processor is configured to execute the interrupt service routine to set a subsequent frame pending bit in the frame header of the immediate acknowledgment frame; if the communication apparatus has a subsequent data frame to be sent, the value of the subsequent frame pending bit is set to 1; otherwise, the value of the subsequent frame pending bit is set to 0.

Preferably, in response to the frame version number of the message frame being 0b10, the processor is configured to execute the interrupt service routine to set the subsequent frame pending bit in the frame header of the immediate acknowledgment frame; if the communication apparatus has a subsequent data frame to be sent, the value of the subsequent frame pending bit is set to 1; otherwise, the value of the subsequent frame pending bit is set to 0.

In further aspect of the present application, a communication apparatus including a processor, a memory and a communication module is provided, wherein the processor, the memory and the communication module are interconnected by lines, and the communication apparatus is configured to execute any one of the above methods.

The present application provides an acknowledgment mechanism suitable for being compatible with different versions of IEEE 802.15.4 by means of a combination of hardware and software, making full use of the high efficiency of hardware acknowledgment and the flexibility of software acknowledgment, effectively reducing power consumption and avoiding over-occupation of CPU time by the interruption software service program.

It is to be understood that the above description of the background art and the summary of the application is merely illustrative and not restrictive.

### BRIEF DESCRIPTION OF THE DRAWINGS

FIG. 1 shows a schematic block diagram of a communication apparatus 100 and a network 200A according to an embodiment of the present application;

FIG. 2 shows a schematic block diagram of the communication apparatus 100 for generating and sending an acknowledgment frame in an IEEE 802.15.4 network according to an embodiment of the present application;

FIG. 3 shows a schematic flow chart of a method for generating and sending an acknowledgment frame in an IEEE 802.15.4 network according to an embodiment of the present application;

FIG. 4 shows a schematic flow chart of the method for generating and sending an acknowledgment frame in an IEEE 802.15.4 network according to another embodiment of the present application;

FIG. 5 shows a format of a frame control field in a message frame according to the IEEE 802.15.4 protocol;

FIG. 6 shows a frame format of an immediate acknowledgment frame according to the IEEE 802.15.4 protocol;

FIG. 7 shows a frame format of an enhanced acknowledgment frame according to the IEEE 802.15.4 protocol;

FIG. 8 shows a block diagram of a communication module 106 of the communication apparatus 100 according to an embodiment of the present application.

### DETAILED DESCRIPTION

The present application will be described more fully hereinafter with reference to the accompanying drawings, which constitute a part of this disclosure and show, by way of illustration, exemplary embodiments. It is to be appreciated that the embodiments shown in the accompanying drawings and described below are merely illustrative and not intended to limit the present application.

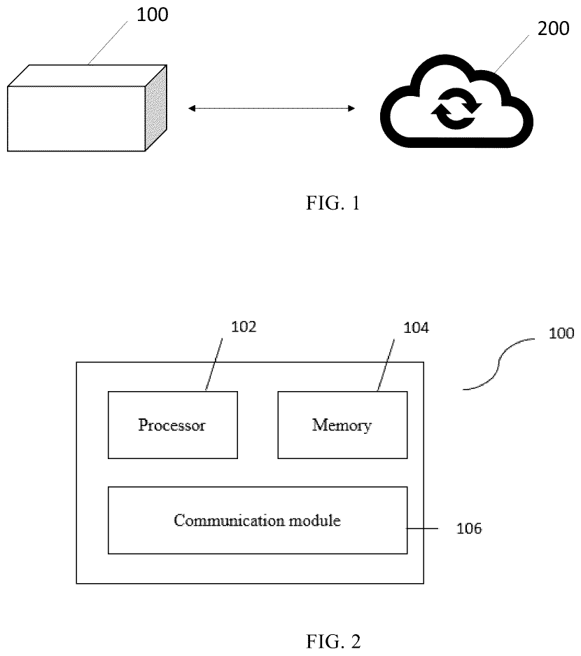

Before describing the technical solutions of the embodiments of the present application, the IEEE 802.15.4 network of the embodiments of the present application and the communication apparatus in the network are first described in conjunction with FIG. 1. FIG. 1 schematically illustrates a communication apparatus 100 and a network 200. The network 200 is an IEEE 802.15.4 network. The communication apparatus 100 is connected to the network 200 and can communicate with the devices in the network 200. It is to be understood that the communication apparatus 100 may be arranged in the network 200.

### Embodiment 1

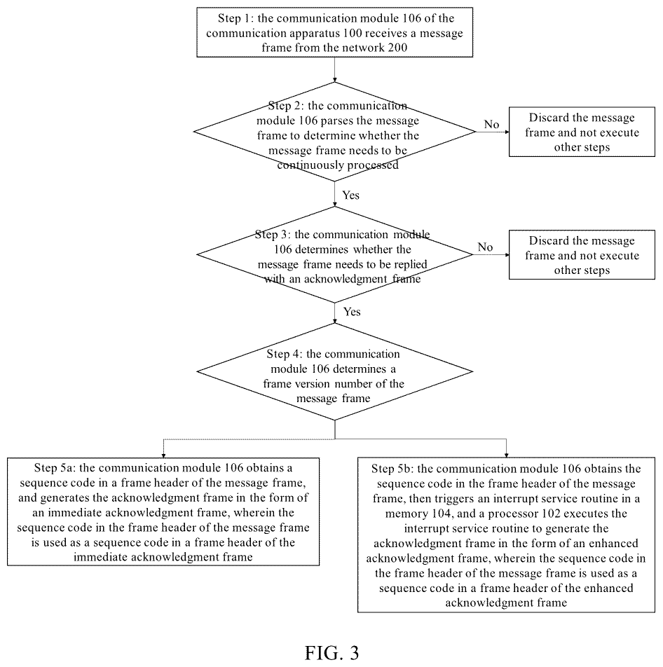

According to one embodiment of the present application, FIG. 2 schematically illustrates a block diagram of the communication apparatus 100, which includes a processor 102, a memory 104 and a communication module 106. It is to be understood that the communication module can be implemented as a hardware module, hardware circuit, chip or the like that implements communication functions.

FIG. 3 schematically illustrates a method for generating and sending an acknowledgment frame in an IEEE 802.15.4 network, the method is performed by the communication apparatus 100, and the method includes following steps.

At step 1, the communication module 106 of the communication apparatus 100 receives a message frame from the network 200.

At step 2, the communication module 106 parses the message frame to determine whether the message frame needs to be continuously processed; if yes, execute step 3; if no, discard the message frame and not execute other steps.

At step 3, the communication module 106 determines whether the message frame needs to be replied with an acknowledgment frame; if yes, proceed to step 4; if no, discard the message frame and not execute other steps.

At step 4, the communication module 106 determines a frame version number of the message frame; if the frame version number of the message frame is 0b00 or 0b01, execute step 5a; if the frame version number of the message frame is 0b10, execute step 5b.

At step 5a, the communication module 106 obtains a sequence code in a frame header of the message frame, and generates the acknowledgment frame in the form of an immediate acknowledgment frame, wherein the sequence code in the frame header of the message frame is used as a sequence code in a frame header of the immediate acknowledgment frame.

At step 5b, the communication module 106 obtains the sequence code in the frame header of the message frame, then triggers an interrupt service routine in a memory 104, and a processor 102 executes the interrupt service routine to generate the acknowledgment frame in the form of an enhanced acknowledgment frame, wherein the sequence code in the frame header of the message frame is used as a sequence code in a frame header of the enhanced acknowledgment frame.

Herein, the immediate acknowledgment frame includes a frame header and a frame trailer, and the enhanced acknowledgment frame includes a frame header, a MAC payload, and a frame trailer.

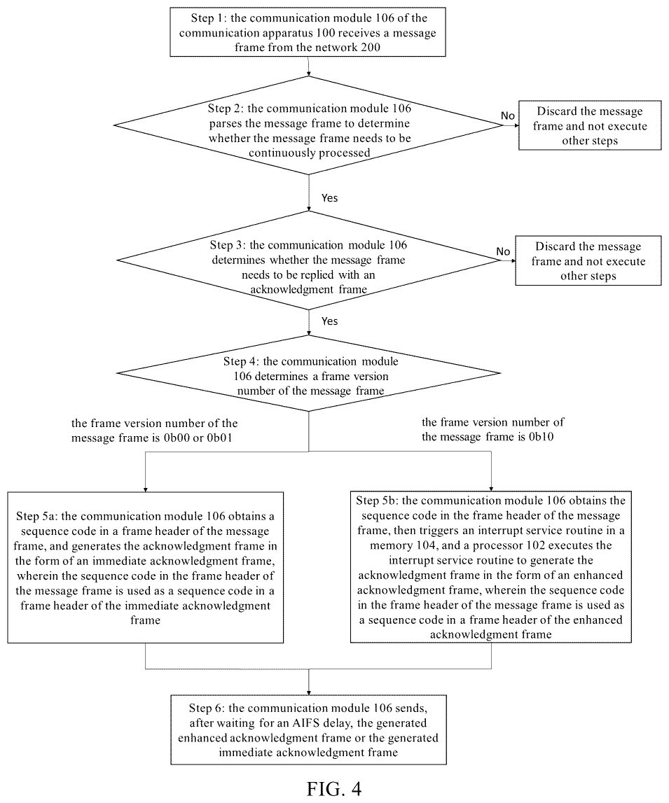

Further, as shown in FIG. 4, after step 5a or step 5b, proceed to step 6, the communication module 106 sends, after waiting for an AIFS delay, the generated enhanced acknowledgment frame or the generated immediate acknowledgment frame.

The above embodiment provides specific operation processes and steps by way of example, but it is to be understood that the protection scope of the present application is not limited thereto.

### EXAMPLES

As an example, the communication apparatus 100 receives a message frame from the network 200 by the communication module 106. The message frame can be categorized into the following types according to the frame type field: a beacon frame, a data frame, a command frame, etc. As an example but not a limitation, the message frame includes a frame header, a MAC payload, and a frame trailer.

As an example but not a limitation, the frame header of the message frame contains a destination address for indicating a destination receiver of the message frame. The frame header of the message frame further includes a sequence code for determining the sequence of the frame. The frame trailer of the message frame further contains a CRC check code for checking whether the message frame is damaged during data transmission to ensure the integrity of the message frame. For example, the CRC check code is a 16-bit value. The message frame further contains an acknowledge request field for indicating whether the message frame requires the receiver to reply with an acknowledgment frame.

Furthermore, the communication module 106 parses the received message frame to determine whether the message frame needs to be continuously processed; If yes, proceed to the next step; if no, discard the message frame and not execute other steps.

As an example but not a limitation, there are many situations for determining whether the message frame is to be continuously processed. For example, it is determined, based on the destination address or the CRC check code in the message frame, whether the message frame needs to be continuously processed. If the destination address in the message frame does not contain the address of the communication apparatus 100, or if the CRC check code is incorrect, then discard the message frame and not execute other steps; otherwise, proceed to other steps to respond to the message frame. For another example, if there is a reserved field in the message frame, that is, if there is an undefined value in a certain field, the communication apparatus 100 will also discard the message frame and will not execute other steps.

Furthermore, the communication module 106 determines whether the message frame needs to be replied with an acknowledgment frame; If yes, proceed to the next step; if not, discard the message frame and not execute other steps.

As an example but not a limitation, determining whether it is needed to reply with an acknowledgment frame is mainly based on the value of the acknowledgment request field in the message frame. If the value of the acknowledgment request field is 1, an acknowledgment frame is needed; if the value of the acknowledgment request field is 0, an acknowledgment frame is not needed.

As an example but not a limitation, determining whether it is needed to reply with an acknowledgment frame may also be based on whether the message frame is a unicast data frame. If the message frame is a unicast data frame, an acknowledgment frame is needed; if not, an acknowledgment frame is not needed.

Furthermore, the communication module 106 determines a frame version number of the message frame.

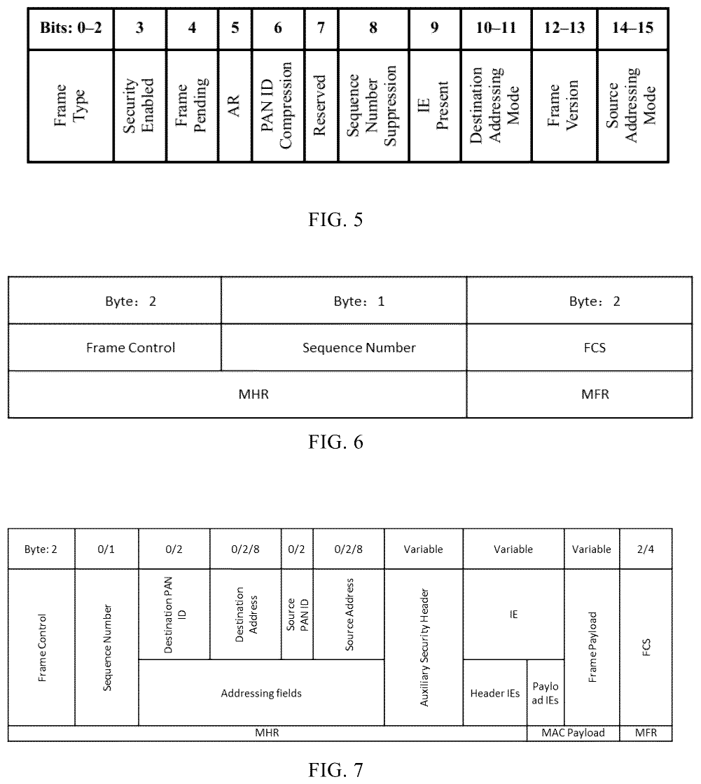

As an example but not a limitation, the format of the frame control field of the message frame is shown in FIG. 5, wherein bits 12-13 of the frame control field are an unsigned integer representing the frame version number of the message frame. The frame version number may be 0b00, 0b01, or 0b10.

Further, if the frame version number of the message frame is 0b00 or 0b01, the communication module 106 obtains the sequence code in the frame header of the message frame and generates the acknowledgment frame in the form of an immediate acknowledgment frame, wherein the sequence code in the frame header of the message frame is used as the sequence code in the frame header of the immediate acknowledgment frame. The immediate acknowledgment frame includes a frame header and a frame trailer.

As an example but not a limitation, the format of the immediate acknowledgment frame is fixed, and the specific format of the immediate acknowledgment frame is shown in FIG. 6. The frame format of the immediate acknowledgment frame is a fixed 5-byte frame including a frame header (MHR) and a frame trailer (MFR). Wherein, the frame header consists of a frame control (2 bytes) and a sequence code (1 byte), and the frame tail consists of a frame check sequence (FCS, 2 bytes) in which it is only necessary to parse out the sequence code in the received message frame by the communication module 106 and use it as the sequence code of the immediate acknowledgment frame. Therefore, it is more efficient to use hardware (i.e., the communication module 106) to automatically parse the message frame and generate the immediate acknowledgment frame, eliminating the need to parse the message frame and generate the acknowledgment frame by software, which saves CPU time used by the software interrupt service routine, and at the same time reduces power consumption.

Furthermore, the processor 102 executes the interrupt service routine to set the subsequent frame pending bit in the frame header of the immediate acknowledgment frame. If the communication apparatus 100 has a subsequent data frame to be sent, the value of the subsequent frame pending bit is set to 1; otherwise, the value of the subsequent frame pending bit is set to 0.

As an example and not a limitation, the subsequent frame pending bit is used for informing the receiver of the acknowledgment frame whether there are other data packets to follow. It is to be understood that in the existing art, some technical solutions set the subsequent frame pending bit by hardware, that is, writing the address list in the register in advance, querying the address list according to the address of the received data packet, and determining whether to continue sending data packets to the receiver of the address after replying with the acknowledgment frame. The present application, however, uses an interrupt service routine in the form of software to set the subsequent frame pending bit. The solution is relatively flexible. The address list is maintained by software and can be updated in real time. At the same time, it also saves space for registers in hardware, overcoming the disadvantage that registers cannot be expanded.

Further, if the frame version number of the message frame is 0b10, the communication module 106 obtains the sequence code in the frame header of the message frame, and triggers the interrupt service routine in the memory 104, and the processor 102 executes the interrupt service routine to generate the acknowledgment frame in the form of an enhanced acknowledgment frame, wherein the sequence code in the frame header of the message frame is used as the sequence code in the frame header of the enhanced acknowledgment frame. The enhanced acknowledgment frame includes a frame header, a MAC payload, and a frame trailer.

As an example and not limitation, the format of the enhanced acknowledgment frame is shown in FIG. 7. The frame header of the enhanced acknowledgment frame includes a frame control (2 bytes), a sequence number (0 or 1 byte), a destination PAN ID (0 or 2 bytes), a destination address (0 or 2 or 8 bytes), a source PAN ID (0 or 2 bytes), a source address (0 or 2 or 8 bytes), an auxiliary security header (variable bytes), and a header information element (Header IE, variable bytes). The frame tail consists of a frame check sequence (FCS, 2 or 4 bytes), and the MAC payload unit consists of a payload information element (Payload IE) and a frame payload (variable bytes). The enhanced acknowledgment frame is similar to the normal message frame in that it is necessary to fill in the address in the frame header and fill in the specific content in the MAC payload field. Therefore, the content that needs to be filled in the enhanced acknowledgment frame is too random, and the corresponding content of each field of the enhanced acknowledgment frame is filled in sequence by the interrupt service routine in the form of software to generate the enhanced acknowledgment frame.

Furthermore, the processor 102 executes the interrupt service routine to set the subsequent frame pending bit in the frame header of the enhanced acknowledgment frame. If the communication apparatus 100 has a subsequent data frame to be sent, the value of the subsequent frame pending bit is set to 1; otherwise, the value of the subsequent frame pending bit is set to 0.

Further, the communication module 106, after waiting for an AIFS delay, sends the generated enhanced acknowledgment frame or immediate acknowledgment frame. As an example and not a limitation, the AIFS delay duration is 192 μs. The AIFS delay is the reserved time by the communication apparatus 100 for a communication device node waiting to send a message frame to change from a sending state to a receiving state.

### Embodiment 2

According to another embodiment of the present application, FIG. 2 schematically illustrates a block diagram of a communication apparatus 100 for generating and sending an acknowledgment frame in an IEEE 802.15.4 network, which includes a processor 102, a memory 104, and a communication module 106.

As an example but not limitation, the communication apparatus 100 is a system-on-chip (SoC chip, also called system on chip), and the communication module 106 is an IEEE 802.15.4 communication module of the communication apparatus 100, which can support communication according to the IEEE 802.15.4 protocol.

Herein, the communication module 106 of the communication apparatus 100 is configured to receive a message frame from the IEEE 802.15.4 network and send the acknowledgment frame; the memory 104 is configured to store an interrupt service routine; the communication module 106 is also configured to: parse the message frame to determine whether the message frame needs to be continuously processed; determine whether the message frame needs to be replied with an acknowledgment frame; and determine a frame version number of the message frame.

Herein, in response to determining that the message frame does not need to be replied with an acknowledgment frame, the processor 102 discards the message frame.

Herein, in response to the frame version number of the message frame being 0b00 or 0b01, the communication module 106 obtains a sequence code in a frame header of the message frame and generates the acknowledgment frame in the form of an immediate acknowledgment frame, wherein the sequence code in the frame header of the message frame is used as a sequence code in a frame header of the immediate acknowledgment frame.

Herein, in response to the frame version number of the message frame being 0b10, the communication module 106 obtains the sequence code in the frame header of the message frame, and then the communication module 106 triggers the interrupt service routine in the memory 104, and the processor 102 executes the interrupt service routine to generate the acknowledgment frame in the form of an enhanced acknowledgment frame, wherein the sequence code in the frame header of the message frame is used as a sequence code in a frame header of the enhanced acknowledgment frame.

Herein, the immediate acknowledgment frame includes a frame header and a frame trailer, and the enhanced acknowledgment frame includes a frame header, a MAC payload, and a frame trailer.

Further, in response to the generated enhanced acknowledgment frame or the generated immediate acknowledgment frame, the communication module 106 sends, after waiting for an AIFS delay, the generated enhanced acknowledgment frame or the generated immediate acknowledgment frame.

Furthermore, the AIFS delay duration is 192 μs.

Preferably, the communication module 106 determines, based on a destination address or a CRC check code in the message frame, whether the message frame needs to be continuously processed; if the destination address in the message frame does not contain the address of the communication apparatus 100, or if the CRC check code is incorrect, then discard the message frame and not execute other steps; otherwise, proceed to process the message frame.

Preferably, the communication module 106 determines, based on a value of an acknowledge request field in the message frame, whether it is needed to reply with the acknowledgment frame; if the value of the acknowledgment request field is 1, the acknowledgment frame is needed; if the value of the reply request field is 0, the acknowledgment frame is not needed.

Preferably, in response to the frame version number of the message frame being 0b00 or 0b01, the processor 102 executes the interrupt service routine to set a subsequent frame pending bit in the frame header of the immediate acknowledgment frame; if the communication apparatus 100 has a subsequent data frame to be sent, the value of the subsequent frame pending bit is set to 1; otherwise, the value of the subsequent frame pending bit is set to 0.

Preferably, in response to the frame version number of the message frame being 0b10, the processor 102 executes the interrupt service routine to set the subsequent frame pending bit in the frame header of the immediate acknowledgment frame; if the communication apparatus 100 has a subsequent data frame to be sent, the value of the subsequent frame pending bit is set to 1; otherwise, the value of the subsequent frame pending bit is set to 0.

It is to be understood that the implementation of the present application is not limited thereto. The components of the communication apparatus for generating and sending an acknowledgment frame in an IEEE 802.15.4 network in the embodiments of the present application may be connected in a manner different from that shown.

### EXAMPLES

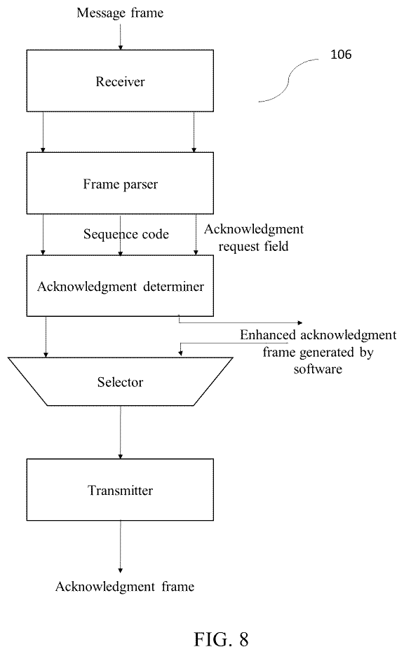

As an example of a specific implementation, FIG. 8 schematically illustrates a block diagram of a communication module 106 of a communication apparatus 100, which includes a receiver configured to receive a message frame from a network and a transmitter configured to send an acknowledgment frame to other devices in the network. The receiver may be, for example, an antenna. The communication module 106 further includes a frame parser which can parse the received message frame field by field to obtain the frame version number, the sequence code and the value of the acknowledgment request field in the message frame. The communication module 106 further includes an acknowledgment determiner configured to determine whether it is needed to reply with an acknowledgment frame, and which acknowledgment frame format should be used if an acknowledgment frame is needed. If the frame version number in the message frame is 0b00 or 0b01, the communication module 106 obtains the sequence code according to the frame parser and generates the acknowledgment frame in the form of an immediate acknowledgment frame. If the frame version number in the message frame is 0b10, the communication module 106 triggers the interrupt service routine in the memory 104, and the processor 102 executes the interrupt service routine to generate the acknowledgment frame in the form of an enhanced acknowledgment frame. The communication module 106 further includes a selector configured to select the generated immediate acknowledgment frame or enhanced acknowledgment frame according to the determination result of the acknowledgment determiner. The communication module 106 further includes a transmitter configured to send the generated acknowledgment frame to the network where the communication apparatus 100 is located.

The above embodiment provides specific operation processes and steps by way of example, but it is to be understood that the protection scope of the present application is not limited thereto.

According to the method and apparatus disclosed in the present application, as an optional implementation method, the communication apparatus includes a processor, a memory, and a communication module, wherein the processor, the memory, and the communication module are interconnected by lines, and the communication apparatus is used to execute any one of the methods described above.

Compared with the existing art, the software-hardware combined acknowledgment technology proposed in the present application has the following advantages: 1) it can simultaneously support the requirements for the acknowledgment mechanism in various versions of IEEE 802.15.4; 2) the efficiency is improved by automatically generating immediate acknowledgment frames by hardware, which reduces the software complexity in the interrupt service routine, thereby reducing the CPU time occupied by the interrupt service routine, and thus improving the system response speed and reducing power consumption; 3) enhanced acknowledgment frames are generated by the interrupt service routine in the form of software, which can meet the flexibility requirements thereof. This solution achieves the effect of simultaneously supporting acknowledgment frame reply by software and hardware by adding a hardware structure in the communication module for determining whether an acknowledgment frame is needed and, if so, which format the acknowledgment frame should use.

While various embodiments of various aspects of the disclosure have been described for the purpose of this disclosure, it shall not be appreciated that the teaching of this disclosure is limited to these embodiments. The features disclosed in a specific embodiment are therefore not limited to that embodiment, but may be combined with the features disclosed in different embodiments. Furthermore, it is to be understood that the method steps described above may be performed sequentially, performed in parallel, combined into fewer steps, split into more steps, combined in a manner different from that described, and/or omitted. Those skilled in the art will understand that there are more possible optional implementations and variants, and various changes and modifications may be made to the above components and configurations without departing from the scope defined by the claims of the present application.

1. A method for generating and sending an acknowledgment frame in an IEEE 802.15.4 network, the method being performed by a communication apparatus, the communication apparatus comprising a processor, a memory, and a communication module, wherein the method comprises:
step 1: receiving, by the communication module of the communication apparatus, a message frame from the IEEE 802.15.4 network;
step 2: parsing, by the communication module, the message frame to determine whether the message frame needs to be continuously processed; if yes, executing step 3;
step 3: determining, by the communication module, whether the message frame needs to be replied with an acknowledgment frame; if yes, proceeding to step 4;
step 4: determining, by the communication module, a frame version number of the message frame; in response to the frame version number of the message frame being 0b00 or 0b01, executing step 5a; in response to the frame version number of the message frame being 0b10, executing step 5b;
step 5a: obtaining, by the communication module, a sequence code in a frame header of the message frame, and generating the acknowledgment frame in a form of an immediate acknowledgment frame, wherein the sequence code in the frame header of the message frame is used as a sequence code in a frame header of the immediate acknowledgment frame;
step 5b: obtaining, by the communication module, the sequence code in the frame header of the message frame, then triggering, by the communication module, an interrupt service routine in the memory, and executing, by a processor, the interrupt service routine to generate the acknowledgment frame in a form of an enhanced acknowledgment frame, wherein the sequence code in the frame header of the message frame is used as a sequence code in a frame header of the enhanced acknowledgment frame;
wherein the immediate acknowledgment frame comprises a frame header and a frame trailer, and the enhanced acknowledgment frame comprises a frame header, a MAC payload, and a frame trailer.

2. The method according to claim 1, wherein after step 5a or step 5b, proceeding to step 6: sending, by the communication module, after waiting for an AIFS delay, the generated enhanced acknowledgment frame or the generated immediate acknowledgment frame.

3. The method according to claim 2, wherein a duration of the AIFS delay is 192 μs.

4. The method according to claim 1, wherein in step 2, determining, based on a destination address or a CRC check code in the message frame, whether the message frame needs to be continuously processed; in response to that the destination address in the message frame does not contain the address of the communication apparatus, or in response to that the CRC check code is incorrect, then discarding the message frame and not executing other steps.

5. The method according to claim 1, wherein in step 3, determining, based on a value of an acknowledgment request field in the message frame, whether it is needed to reply with the acknowledgment frame; in response to the value of the acknowledgment request field being 1, the acknowledgment frame is needed; in response to the value of the reply request field being 0, the acknowledgment frame is not needed.

6. The method according to claim 1, wherein step 5a further comprises: executing, by the processor, the interrupt service routine to set a subsequent frame pending bit in the frame header of the immediate acknowledgment frame, and in response to that the communication apparatus has a subsequent data frame to be sent, setting a value of 1 for the subsequent frame pending bit, otherwise, setting a value of 0 for the subsequent frame pending bit.

7. The method according to claim 1, wherein step 5b further comprises: executing, by the processor, the interrupt service routine to set a subsequent frame pending bit in the frame header of the enhanced acknowledgment frame, and in response to that the communication apparatus has a subsequent data frame to be sent, setting a value of 1 for the subsequent frame pending bit, otherwise, setting a value of 0 for the subsequent frame pending bit.

8. A communication apparatus for generating and sending an acknowledgment frame in an IEEE 802.15.4 network, wherein the communication apparatus comprises a processor, a memory, and a communication module, wherein:
the communication module of the communication apparatus is configured to receive a message frame from the IEEE 802.15.4 network and send the acknowledgment frame;
the memory is configured to store an interrupt service routine;
the communication module is also configured to:
parse the message frame to determine whether the message frame needs to be continuously processed;
determine whether the message frame needs to be replied with the acknowledgment frame;
determine a frame version number of the message frame;
the processor is configured to discard the message frame in response to determining that the message frame does not need to be replied with the acknowledgment frame;
the communication module is configured to obtain a sequence code in a frame header of the message frame and generate the acknowledgment frame in a form of an immediate acknowledgment frame, in response to the frame version number of the message frame being 0b00 or 0b01; wherein the sequence code in the frame header of the message frame is used as a sequence code in a frame header of the immediate acknowledgment frame;
the communication module is configured to obtain a sequence code in the frame header of the message frame and trigger the interrupt service routine in the memory, and the processor is configured to execute the interrupt service routine to generate the acknowledgment frame in a form of an enhanced acknowledgment frame, in response to the frame version number of the message frame being 0b10; wherein the sequence code in the frame header of the message frame is used as a sequence code in a frame header of the enhanced acknowledgment frame;
wherein the immediate acknowledgment frame comprises a frame header and a frame trailer, and the enhanced acknowledgment frame comprises a frame header, a MAC payload, and a frame trailer.

9. The communication apparatus according to claim 8, wherein in response to the generated enhanced acknowledgment frame or the generated immediate acknowledgment frame, the communication module is configured to, after waiting for an AIFS delay, send the generated enhanced acknowledgment frame or the immediate acknowledgment frame.

10. The communication apparatus according to claim 9, wherein a duration of the AIFS delay is 192 μs.

11. The communication apparatus according to claim 8, wherein the communication module is configured to determine, based on a destination address or a CRC check code in the message frame, whether the message frame needs to be continuously processed; in response to that the destination address in the message frame does not contain the address of the communication apparatus, or in response to that the CRC check code is incorrect, then the communication module is configured to discard the message frame and not execute other steps; otherwise, proceed to process the message frame.

12. The communication apparatus according to claim 8, wherein the communication module is configured to determine, based on a value of an acknowledge request field in the message frame, whether it is needed to reply with the acknowledgment frame; in response to the value of the acknowledgment request field being 1, the acknowledgment frame is needed; in response to the value of the reply request field being 0, the acknowledgment frame being not needed.

13. The communication apparatus according to claim 8, wherein in response to the frame version number of the message frame being 0b00 or 0b01, the processor is configured to execute the interrupt service routine to set a subsequent frame pending bit in the frame header of the immediate acknowledgment frame; in response to that the communication apparatus has a subsequent data frame to be sent, the value of the subsequent frame pending bit is set to 1; otherwise, the value of the subsequent frame pending bit is set to 0.

14. The communication apparatus according to claim 8, wherein in response to the frame version number of the message frame being 0b10, the processor is configured to execute the interrupt service routine to set the subsequent frame pending bit in the frame header of the immediate acknowledgment frame; in response to that the communication apparatus has a subsequent data frame to be sent, the value of the subsequent frame pending bit is set to 1; otherwise, the value of the subsequent frame pending bit is set to 0.

15. A communication apparatus comprising a processor, a memory and a communication module, the processor, the memory, and the communication module are interconnected by lines, and the communication apparatus is configured to perform steps of:
step 1: receiving, by the communication module of the communication apparatus, a message frame from the IEEE 802.15.4 network;
step 2: parsing, by the communication module, the message frame to determine whether the message frame needs to be continuously processed; if yes, executing step 3;
step 3: determining, by the communication module, whether the message frame needs to be replied with an acknowledgment frame; if yes, proceeding to step 4;
step 4: determining, by the communication module, a frame version number of the message frame; in response to the frame version number of the message frame being 0b00 or 0b01, executing step 5a; in response to the frame version number of the message frame being 0b10, executing step 5b;
step 5a: obtaining, by the communication module, a sequence code in a frame header of the message frame, and generating the acknowledgment frame in a form of an immediate acknowledgment frame, wherein the sequence code in the frame header of the message frame is used as a sequence code in a frame header of the immediate acknowledgment frame;
step 5b: obtaining, by the communication module, the sequence code in the frame header of the message frame, then triggering, by the communication module, an interrupt service routine in the memory, and executing, by a processor, the interrupt service routine to generate the acknowledgment frame in a form of an enhanced acknowledgment frame, wherein the sequence code in the frame header of the message frame is used as a sequence code in a frame header of the enhanced acknowledgment frame;
wherein the immediate acknowledgment frame comprises a frame header and a frame trailer, and the enhanced acknowledgment frame comprises a frame header, a MAC payload, and a frame trailer.

16. The communication apparatus according to claim 15, wherein after step 5a or step 5b, the communication apparatus is configured to proceed to step 6: sending, by the communication module, after waiting for an AIFS delay, the generated enhanced acknowledgment frame or the generated immediate acknowledgment frame.

17. The communication apparatus according to claim 15, wherein the communication apparatus is configured to: in step 2, determine, based on a destination address or a CRC check code in the message frame, whether the message frame needs to be continuously processed; in response to that the destination address in the message frame does not contain the address of the communication apparatus, or in response to that the CRC check code is incorrect, then discard the message frame and not execute other steps.

18. The communication apparatus according to claim 15, wherein the communication apparatus is configured to: in step 3, determine, based on a value of an acknowledgment request field in the message frame, whether it is needed to reply with the acknowledgment frame; in response to the value of the acknowledgment request field being 1, the acknowledgment frame is needed; in response to the value of the reply request field being 0, the acknowledgment frame is not needed.

19. The communication apparatus according to claim 15, wherein step 5a further comprises: executing, by the processor, the interrupt service routine to set a subsequent frame pending bit in the frame header of the immediate acknowledgment frame, and in response to the communication apparatus having a subsequent data frame to be sent, setting a value of 1 for the subsequent frame pending bit, otherwise, setting a value of 0 for the subsequent frame pending bit.

20. The communication apparatus according to claim 15, wherein step 5b further comprises: executing, by the processor, the interrupt service routine to set a subsequent frame pending bit in the frame header of the enhanced acknowledgment frame, and in response to that the communication apparatus has a subsequent data frame to be sent, setting a value of 1 for the subsequent frame pending bit, otherwise, setting a value of 0 for the subsequent frame pending bit.
